(19) United States
(12) Patent Application Publication
(10) Pub. No.: US 2003/0119215 A1
(43) Pub. Date: Jun. 26, 2003

(54) Method and system for determining a performance of plasma etch equipment

(76) Inventor: Joseph Louis Petrucci JR., New Milford, CT (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/027,823

(22) Filed: Dec. 21, 2001

(51) Int. Cl. C23F 1/00; H01L 21/00

(52) U.S. Cl. 438/14; 438/9; 156/345.24

(57) ABSTRACT

A method of determining a performance of plasma etch equipment is provided. The method comprises extracting data that depend on the performance of plasma etch equipment, during etching of the wafer, for example by calculating an etch rate and by calculating a non-uniformity of a film being etched. After that, the extracted data are compared to predetermined data, and on the basis of a result of comparing the extracted data with predetermined data the performance of the plasma etch equipment is determined. Further, a system for determining a performance of plasma etch equipment is provided.

### FIELD OF THE INVENTION

The present invention generally relates to a method of determining a performance of plasma etch equipment, and more particularly to a method of determining the performance during normal wafer processing. The present invention further relates to a system for determining a performance of plasma etch equipment.

### BACKGROUND OF THE INVENTION

Etching in a plasma environment is a well-known technique in the semiconductor industry. Plasma etching has several significant advantages when compared to wet etching. For example, plasmas are much easier to start and stop than immersion wet etching. Further, plasma etch processes are less sensitive to temperature changes of the wafer. Thus, besides further advantages that are, for example, related to the production of small features, plasma etching is much more repeatable than wet etching.

In order to maintain the repeatability, it is important to monitor the performance of plasma etch equipment, since such performance changes with time.

Prior art techniques use test wafers with a blanket film, for example polysilicon, oxide, or aluminum that are etched for a given time. By dividing the thickness of material removed through the process time, the etch rate of the equipment can be determined.

Unfortunately, there are disadvantages related to the prior art monitoring. For example, non-production wafers are required to test the etch rate; thereby, material is wasted. Further, the plasma etch equipment is required to be used for a non-production task, thus reducing its availability. Moreover, the prior art etch rate tests are mostly performed only once a day. Consequently, an unexpected change in performance of a particular etch tool between two monitoring runs on different days is not detected. This can influence the quality of the wafers produced. Further, the yield of the production is reduced.

The present invention seeks to solve the above mentioned problems and to provide a method and a system for determining a performance of plasma etch equipment, thereby reducing the number of test wafers and increasing the tool availability by reducing non-production time. Further, production quality and yield shall be improved.

### BRIEF DESCRIPTION OF THE DRAWINGS

FIG. 1 is flow diagram illustrating a preferred embodiment of a method according to the present invention;

FIG. 2 is a block diagram illustrating preferred embodiments of systems according to the present invention;

FIG. 3 is a diagram showing an IEP (interferometric endpoint) signal versus time; and

FIG. 4 is a diagram showing an OES (optical emission spectroscopy) signal versus time.

### DETAILED DESCRIPTION OF PREFERRED EMBODIMENTS

According to the invention, a method of determining a performance of plasma etch equipment 10 is provided, the method comprising the steps of

extracting data that depend on the performance of plasma etch equipment 10, during normal wafer processing,

comparing the extracted data with predetermined data, and

deciding whether the performance of the plasma etch equipment 10 is acceptable, on the basis of a result of comparing the extracted data with predetermined data.

The present invention further relates to a system for determining a performance of plasma etch equipment 10, the system comprising

means 12 for extracting data that depend on the performance of plasma etch equipment 10, during normal wafer processing,

means 14 for comparing the extracted data with predetermined data, and

means 14 for deciding whether the performance of the plasma etch equipment 10 is acceptable, on the basis of a result of comparing the extracted data with predetermined data.

There are several advantages related to the method and to the system according to the present invention. It is possible to extract data that depend on the performance of plasma etch equipment during normal wafer processing. Thus, the performance of plasma etch equipment can be monitored without using test wafers, thereby reducing an undesired loss of material. Further, the tool availability is increased by reducing the non-production time. On the basis of the method and the system according to the present invention, plasma etch equipment can be monitored continuously. Thus, an unexpected change in performance will be noticed and adequate measures can be taken, for example removing a particular tool from the production line.

In particular, it is desirable to calculate etch rate data and non-uniformity data during plasma etching, since these data can be compared to historical data as well as to limits of a statistical process control. The calculation of etch rate and non-uniformity is preferably performed on the basis of endpoint data obtained by the analysis of IEP signals and/or OES signals.

Generally, the present invention is used in conjunction with etching a film formed on a substrate material. For example, the present invention may be used to monitor plasma etching of dielectric or conductive layers formed over a semiconductor wafer.

These and other advantages are described and explained in further detail with reference to the accompanying drawings.

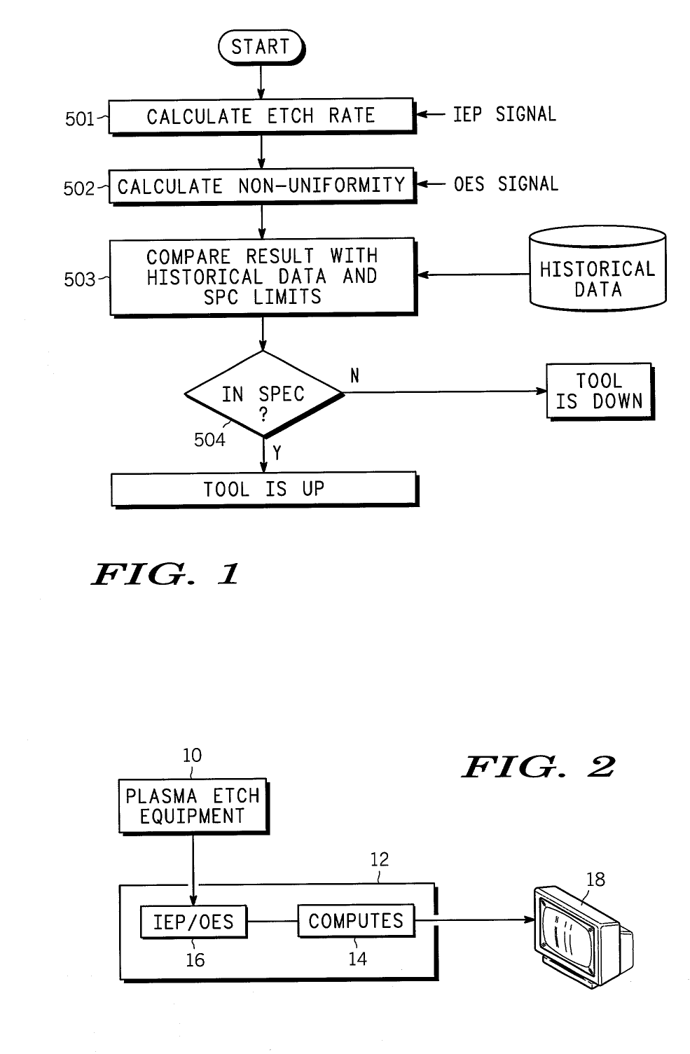

FIG. 1 is flow diagram illustrating a preferred embodiment of a method according to the present invention.

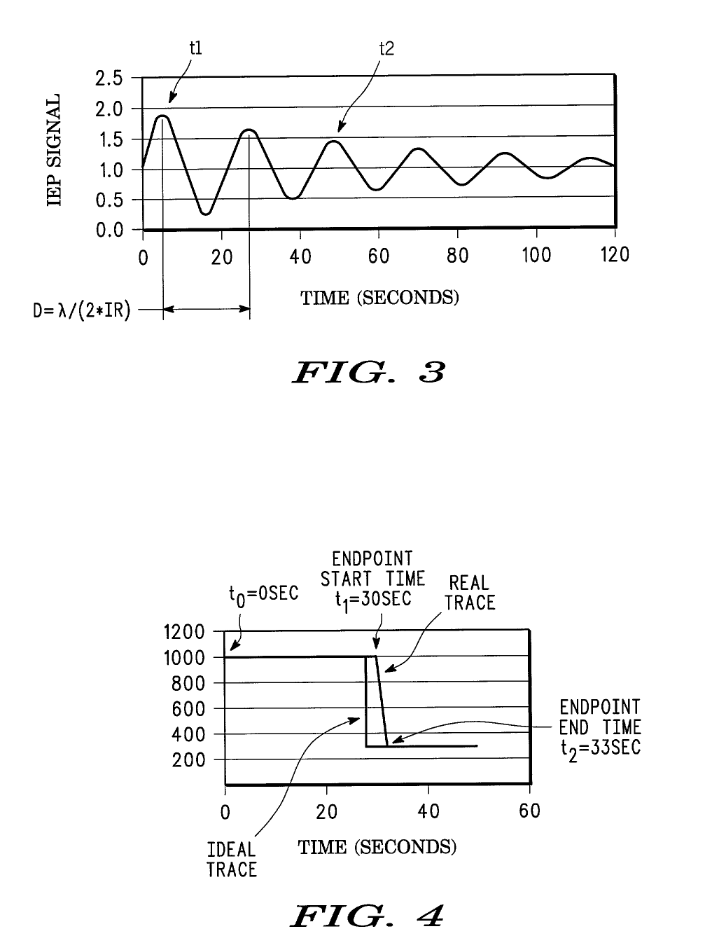

After starting the process, in step S01 an etch rate is calculated. The etch rate is calculated, for example, by analyzing an IEP signal which will be described further below with reference to FIG. 3. The etch rate can also be calculated on the basis of an OES signal. Such analysis will be described further below with reference to FIG. 4.

After calculating the etch rate, in step S02 the non-uniformity of a film to be etched is calculated. The calculation of the non-uniformity is performed on the basis of an OES signal which will be described with reference to FIG. 4 further below.

After calculating the non-uniformity, in step S03 the results of etch rate calculation and non-uniformity calculation are compared with historical data and/or statistical process control (SPC) limits.

In step S04 it is decided, whether the calculated etch rate and the calculated non-uniformity are within a specification, on the basis of the step of comparing (S03). If the results are within the specification it is decided that the plasma etch tool is up, and normally no measures have to be taken. If both or one of the calculated values is not in the specification, it is decided that the tool is down. In this case, for example, the tool can be removed from the production line.

FIG. 2 is a block diagram illustrating preferred embodiments of systems according to the present invention. The plasma etch equipment 10 is monitored by means 12 for extracting data from the plasma etch equipment 10. Such means 12 for extracting data comprise an IEP system 16 and/or and OES system 16 in communication with a computer 14. The computer 14 calculates from OES signals, from IEP signals or from IEP and OES signals an etch rate and a non-uniformity. Further, the computer compares the calculation results with historical data and SPC limits. It is decided whether the results are in the specification. The decision and/or any other data can be indicated by indication means 18.

FIG. 3 is a diagram showing an IEP signal versus time. The etch rate in nm/min is, for example, calculated on the basis of the interferometric signal by using the formula

$$ER = \frac{D \cdot {N}_{P} \cdot 60}{{t}_{2} - {t}_{1}}$$

wherein D is the thickness of a film being etched in nm, N_{P} is the number of periods between the times t₁ and t₂ (in sec) and wherein D is calculated according to the formula

$$D = \frac{λ}{2 \cdot IR}$$

wherein λ is a laser wavelength in nm used for producing IEP signals and IR is the index of refraction of the film being etched.

If, for example, the wavelength is λ=254 nm, the index of refraction is IR=1.46, the number of periods of the interferometric signal is N_{P}=2, and the corresponding times are t₁=8 sec and t₂=48 sec, this results in a thickness of the film to be etched of D=87 nm and, finally, in an etch rate of ER=261 nm/min.

Such calculation can be automatically performed by finding all peaks and valleys of the interferometric signal. A peak is for example defined as a channel having a value that is larger than the value in neighboring channels. Correspondingly, a valley is defined as a channel with a value which is smaller than the values of neighboring channels. After finding the peaks and valleys, the times of peaks and valleys can be determined. From this information, the etch rate can be calculated with a small statistical error.

The described etch rate algorithm can be performed on the basis of all peaks and/or on the basis of all valleys. However, also only several of the peaks and valleys determined can be used. In a preferred embodiment, the user decides how to perform the etch rate algorithm with respect to which data are to be used for the calculation.

FIG. 4 is a diagram showing an OES signal versus time. The number of counts of a certain wavelength of an optical emission spectrum is plotted versus time. In the present case, various times related to the endpoint of an etching process have to be determined on the basis of the extinction of an etch product. Under ideal conditions, in which a film being etched has a non-uniformity of 0%, i.e. the film is completely uniform, the OES signal has the form indicated by “ideal trace”. However, under real conditions, the film being etched is not completely uniform, so that the endpoint start time t₁ differs from the endpoint end time t₂, resulting in the “real trace” as indicated in FIG. 4. In the present example, the endpoint end time is three seconds later than the endpoint start time.

The non-uniformity of the film being etched can be determined by determining the start time t₀. The average value of an initial signal is determined; the time to begin the averaging can be determined by the user, and also the number of points that are involved into the averaging process. After that, the endpoint start time t₁ is determined by obtaining a certain percentage of the average value determined before. Alternatively, an absolute signal value can be compared with a predetermined threshold value. Which of the methods are used for determining the endpoint start time t₁ is, for example, defined by a user. After that, the endpoint end time t₂ is determined. From the times t₀, t₁ and t₂, the non-uniformity U of the film being etched can be calculated, which is, in percent,

$$U = \frac{{t}_{2} - {t}_{1}}{{t}_{2} - {t}_{0}} \times 100.$$

In the example illustrated in FIG. 4, this would result in a non-uniformity of U=(33−30)/(33−0)=9.1%.

The OES signal as illustrated in FIG. 4 can also be used to calculate the etch rate. For this, the thickness D of the film being etched must be determined. Then, the etch rate ER in nm/min can be determined by taking the film thickness D and dividing it by the average of the endpoint start time t₁ and the endpoint end time t₂ (D in nm and t₁, t₂ in sec):

$$ER = \frac{D \cdot 60}{( {t}_{1} + {t}_{2} ) / 2}$$

Thus, several methods and combinations of methods are provided in order to monitor the etch tool performance during normal wafer processing.

While the invention has been described in terms of particular structures, devices and methods, those of skill in the art will understand based on the description herein that it is not limited merely to such examples and that the full scope of the invention is properly determined by the claims that follow.

1. A method of determining a performance of plasma etch equipment, comprising the steps of
etching a semiconductor wafer using the plasma etch equipment,
extracting data that depend on the performance of plasma etch equipment, during etching of the semiconductor wafer,
comparing the extracted data with predetermined data, and
deciding whether the performance of the plasma etch equipment is acceptable, on the basis of a result of comparing the extracted data with predetermined data.

2. The method according to claim 1, wherein the step of extracting data comprises calculating an etch rate.

3. The method according to claim 1, wherein the step of extracting data comprises calculating a non-uniformity of an etched surface.

4. The method according to claim 2, wherein the etch rate is calculated from interferometric endpoint (IEP) signals.

5. The method according to claim 2, wherein the etch rate is calculated from optical emission spectroscopy (OES) signals.

6. The method according to claim 3, wherein the non-uniformity is calculated from optical emission spectroscopy (OES) signals.

7. The method according to claim 4, wherein the etch rate ER in nm/min is calculated according to the formula
$$ER = \frac{D \cdot {N}_{P} \cdot 60}{{t}_{2} - {t}_{1}}$$
wherein
D is the thickness of a film being etched in nm,
Nₚ is the number of periods between the times t₁ and t₂ (in sec) and
wherein D is calculated according to the formula
$$D = \frac{λ}{2 \cdot IR}$$
wherein
λ is a laser wavelength used for producing IEP signals and
IR is the index of refraction of the film being etched.

8. The method according to claim 5, wherein the etch rate ER in nm/min is calculated according to the formula
$$ER = \frac{D \cdot 60}{( {t}_{1} + {t}_{2} ) / 2}$$
wherein
D is the thickness of a film being etched in nm,
t₁ is an endpoint start time in sec and
t₂ is an endpoint end time in sec.

9. The method according to claim 1, wherein the predetermined data comprise of stored historical data.

10. The method according to claim 1, wherein the predetermined data comprise of statistical process control (SPC) data.

11. The method according to claim 6, wherein the non-uniformity U is calculated according to the formula
$$U = \frac{{t}_{2} - {t}_{1}}{{t}_{2} - {t}_{0}} \times 100$$
wherein
t₀ is an etching start time,
t₁ is an endpoint start time and
t₂ is an endpoint end time.

12. A method of determining a performance of plasma etch equipment, comprising the steps of
providing a substrate having a film to be etched,
etching the film using the plasma etch equipment,
calculating an etch rate of the film during etching of the film,
calculating a non-uniformity of the film during etching of the film,
comparing the calculated data with predetermined data, and
deciding whether the performance of the plasma etch equipment is acceptable, on the basis of a result of comparing the calculated data with predetermined data.

13. The method according to claim 12, wherein the etch rate is calculated from interferometric endpoint (IEP) signals.

14. The method according to claim 12, wherein the etch rate is calculated from optical emission spectroscopy (OES) signals.

15. The method according to claim 12, wherein the non-uniformity is calculated from optical emission spectroscopy (OES) signals.

16. A system for determining a performance of plasma etch equipment, comprising
means for extracting data that depend on the performance of plasma etch equipment, during an etch operation,
means for comparing the extracted data with predetermined data, and
means for deciding whether the performance of the plasma etch equipment is acceptable, on the basis of a result of comparing the extracted data with predetermined data.

17. The system according to claim 16, wherein the means for extracting data comprise means for calculating an etch rate.

18. The system according to claim 16, wherein the means for extracting data comprise means for calculating a non-uniformity of an etched surface.

19. The system according to claim 17, wherein means for calculating the etch rate from interferometric end-point (IEP) signals are provided.

20. The system according to claim 17, wherein means for calculating the etch rate from optical emission spectroscopy (OES) signals are provided.

21. The system according to claim 18, wherein means for calculating the non-uniformity from optical emission spectroscopy (OES) signals are provided.

22. A system for determining a performance of plasma etch equipment, comprising
means for calculating an etch rate during an etch operation,
means for calculating a non-uniformity of a film being etched during the etch operation,
means for comparing the calculated data with predetermined data, and
means for deciding whether the performance of the plasma etch equipment is acceptable, on the basis of a result of comparing the calculated data with predetermined data.
